(19) United States
(12) Patent Application Publication
(10) Pub. No.: US 2016/0066686 A1
(43) Pub. Date: Mar. 10, 2016

(54) ADJUSTABLE SUPPORT FOR ELECTRONIC DEVICE

(71) Applicants: Fu Tai Hua Industry (Shenzhen) Co., Ltd., Shenzhen (CN); HON HAI PRECISION INDUSTRY CO., LTD., New Taipei (TW)

(72) Inventors: CHIH-SAN CHIANG, New Taipei (TW); YU-ZHOU ZHUANG, Shenzhen (CN); LING-JUAN JIANG, Shenzhen (CN); HUA-DONG CHENG, Shenzhen (CN)

(21) Appl. No.: 14/790,296

(22) Filed: Jul. 2, 2015

(30) Foreign Application Priority Data
Sep. 5, 2014 (CN) 201410450463.8

(51) Int. Cl. A47B 23/04; F16B 2/00; H05K 5/02; F16B 1/00

(52) U.S. Cl. CPC A47B 23/043; F16B 1/00; F16B 2/005; H05K 5/0204; F16B 2001/0035

(57) ABSTRACT

An adjustable support for supporting an electronic device includes a first, a second and a third frame rotatably connected to two end portions of the first frame. Each frame includes a number of sliding limit structures on one surface of the frame. The frames are configurable into at least the following positions: a first position in which the first and second frames are flat and the third frame is at a non-zero angle to the first frame, and a second position in which the first and the third frames are flat and the second frame is at a non-zero angle to the first frame. One of the flat frames supports the lower edge of the electronic device with a selected sliding limit structure of the flat frames stopping the lower edge of the electronic device, and the standing frame acts as a back stand for the electronic device.

### CROSS-REFERENCE TO RELATED APPLICATIONS

This application claims priority to Chinese Patent Application No. 201410450463.8 filed on Sep. 5, 2014, the contents of which are incorporated by reference herein.

### FIELD

The subject matter herein generally relates to adjustable supports for supporting electronic devices at a selected one of different viewing angles.

### BACKGROUND

Existing supports can be used for supporting electronic devices at a few viewing angles while the electronic devices in use.

### BRIEF DESCRIPTION OF THE DRAWINGS

Implementations of the present disclosure will now be described, by way of example only, with reference to the attached figures.

FIG. 1 is a diagrammatic view of an adjustable support.

FIG. 2 is a side view showing the support of FIG. 1 in a first state of use.

FIG. 3 is a side view showing the support of FIG. 1 in a second state of use.

FIG. 4 is an isometric view showing the support of FIG. 1 in a third state of use.

FIG. 5 is a side view showing the support of FIG. 1 in a fourth state of use.

FIG. 6 is a side view showing the support of FIG. 1 in a fifth state of use.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features. The present disclosure, including the accompanying drawings, is illustrated by way of examples and not by way of limitation.

Several definitions that apply throughout this disclosure will now be presented.

References to “a/an” or “one” embodiment in this disclosure are not necessarily to the same embodiment, and such references mean “at least one.” The term “comprising” means “including, but not necessarily limited to”; it specifically indicates open-ended inclusion or membership in a so-described combination, group, series and the like.

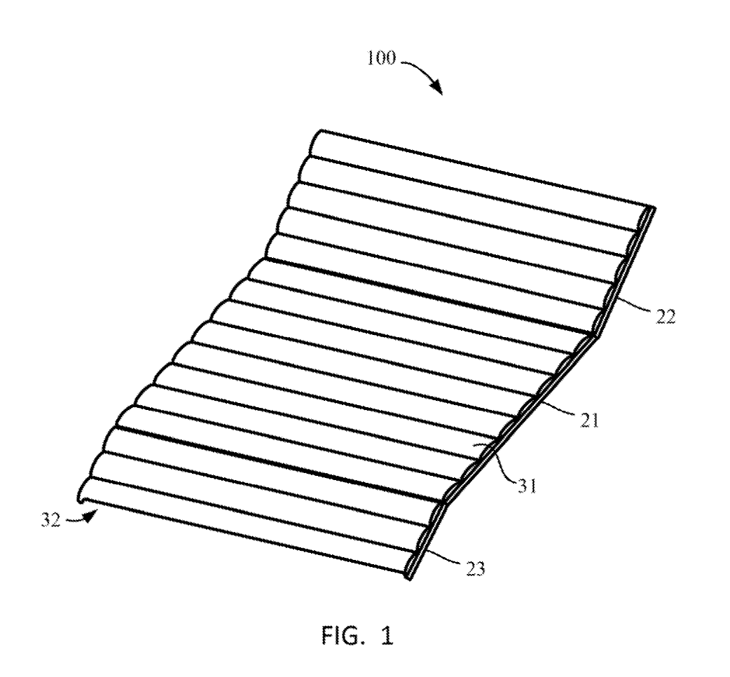

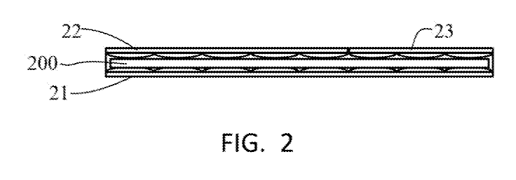

FIG. 1 is a diagrammatic view of an adjustable support. In the embodiment as shown in FIG. 1, an adjustable support 100 is configured for giving protection to an electronic device 200 (as shown in FIG. 2) and supporting the electronic device 200 at one of a large number of selectable viewing angles. In the embodiment, the support 100 includes a first frame 21, a second frame 22, and a third frame 23. In the embodiment, the second frame 22 and the third frame 23 are rotatably connected to two opposite end portions of the first frame 21.

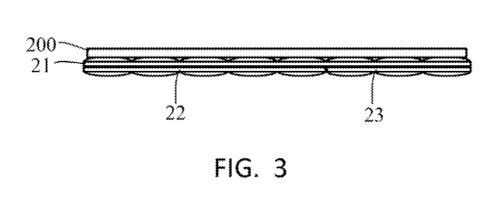

FIGS. 2 and 3 show that the first frame 21 has an overall length and width slightly greater than those of the electronic device 200, and the second frame 22 and the third frame 23 has a combined overall length and width which are slightly greater than those of the first frame 21 and the electronic device 200.

In the illustrated embodiment as shown in FIG. 2, the first, second and third frames can be configurable into a first position in which the first frame 21 covers one surface of the electronic device 200, and the second frame 22 and the third frame 23 are connected together and cover an opposing surface of the electronic device, in order to protect the electronic device 200 when the electronic device 200 is not in use.

In the illustrated embodiment as shown in FIG. 3, the first, second and third frames can be further configurable into a second position in which the first frame 21 covers one surface of the electronic device 200, such as a rear surface of the electronic device 200, and the second frame 22 and the third frame 23 can be folded together with the first frame 21, when the electronic device 200 is in use.

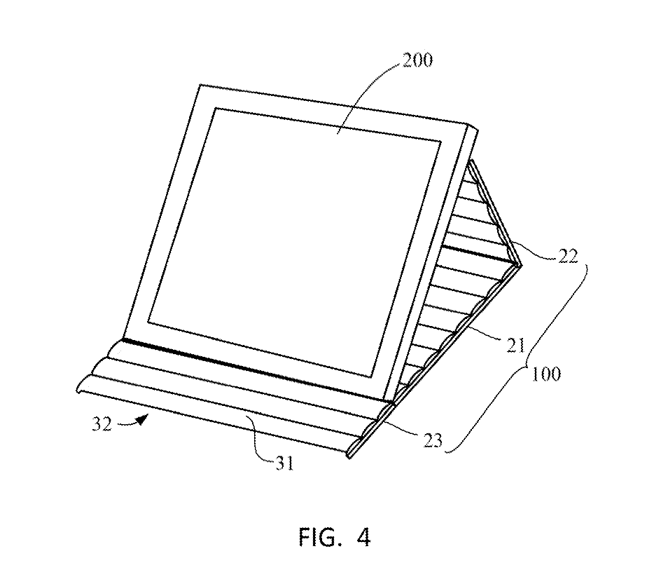

In the embodiment, each of the frames 21, 22, and 23 includes a number of sliding limit structures 31 on a surface of each frame. In the embodiment, the sliding limit structures 31 are ridges protruding from the surface of the frame and parallel to each other. In other embodiments, the sliding limit structures 31 can be protruding portions on the surface of the frame or grooves defined on the surface of the frame. Frames 21 and 23 are preferably of unequal size, and particular have a different number of limit structures 31, to provide different support configurations as discussed with respect to FIGS. 4-6.

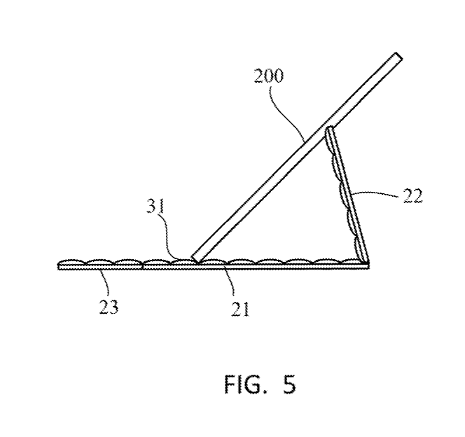

In the illustrated embodiment as shown in FIGS. 4 and 5, the frames 21, 22, and 23 can be further configurable into a third position in which the first frame 21 and the third frame 23 are flat and the second frame 22 is at a non-zero angle to the first frame 21. In the illustrated embodiment, the first frame 21 or the third frame 23 can support the lower edge of the electronic device 200 with a selected sliding limit structure 31 of the first frame 21 or the third frame 23 stopping the lower edge of the electronic device 200, and the second frame 22 acts as a back stand for the electronic device 200. The electronic device 200 is thus supported at one of a large number of selectable viewing angles.

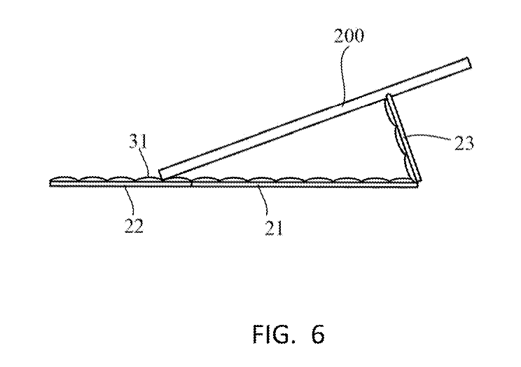

In the illustrated embodiment as shown in FIG. 6, the frames 21, 22, and 23 can be further configurable into a fourth position in which the first frame 21 and the second frame 22 are flat and the third frame 23 is at a non-zero angle to the first frame 21. In the illustrated embodiment, the first frame 21 or the second frame 22 can support the lower edge of the electronic device 200 with a selected sliding limit structure 31 of the first frame 21 or the second frame 22 stopping the lower edge of the electronic device 200, and the third frame 23 acts as a back stand for the electronic device 200.

FIGS. 4-6 further show that, when one of the second frame 22 or the third frame 23 is rotated to stand up relative to the first frame 21 to support the electronic device 200, the other frame which is flat and is connected in parallel to the first frame 21 can increase an amount of the sliding limit structures 31 for stopping the lower edge of the electronic device 200, so as to increase an amount of the selectable viewing angles for the electronic device 200.

In the embodiment, an out portion of each sliding limit structure 31 is made of flexible and high friction material, such as silicone, rubber, plastic, and thermoplastic polyurethane material, so as to maintain the electronic device 200 at a fixed viewing angle when the support 100 supports the electronic device 200 in a stand position, such as shown in FIGS. 4-6. This high friction material will grip the lower edge of the electronic device 200 so that the lower edge of the electronic device 200 does not slide apart from the selected sliding limit structure 31.

In the embodiment, at least part of each sliding limit structure 31 may be made of magnetic material. In an alternative embodiment, at least part of the frames 21, 22 and 23 may be made of magnetic material. The magnetic material is configured to attract the lower edge of the electronic device to the selected sliding limit structure, to maintain the electronic device at a fixed viewing angle when the lower edge of the electronic device is stopped at the selected sliding limit structure. In the embodiment, the magnetic material is further configured to attract the frames 21, 22 and 23 to the surfaces of the electronic device 200 as shown in FIG. 2, or attract the second frame 22 and the third frame 23 to the first frame 21 as shown in FIG. 3.

In the embodiment, each of the second frame 22 and the third frame 23 defines a notch 32 on a free end portion thereof, and the notch 32 is configured to grip the electronic device 200 (e.g., with a high friction surface such as a rubber) when a rear surface of the electronic device 200 is in contact with an end portion which has the notch, in order to allow the electronic device 200 to be maintained at a fixed viewing angle.

The embodiments shown and described above are only examples. Even though numerous characteristics and advantages of the present technology have been set forth in the foregoing description, together with details of the structure and function of the present disclosure, the disclosure is illustrative only, and changes can be made in the detail, including in particular the matters of shape, size, and arrangement of parts within the principles of the present disclosure, up to and including the full extent established by the broad general meaning of the terms used in the claims.

What is claimed is:

1. An adjustable support for supporting an electronic device, comprising:
a first frame comprising two opposite end portions; and
a second frame and a third frame rotatably connected to the two end portions of the first frame, wherein each frame comprises a plurality of sliding limit structures on one surface of the frame;
wherein the first, second and third frames are configurable into at least the following positions:
a first position in which the first and second frames are flat and the third frame is at a non-zero angle to the first frame, wherein the first or second frame supports the lower edge of the electronic device with a selected sliding limit structure of the first or second frame stopping the lower edge of the electronic device, and the third frame acts as a back stand for the electronic device; and
a second position in which the first and the third frames are flat and the second frame is at a non-zero angle to the first frame, wherein the first or third frame supports the lower edge of the electronic device with a selected sliding limit structure of the first or third frame stopping the lower edge of the electronic device, and the second frame acts as a back stand for the electronic device.

2. The adjustable support as described in claim 1, wherein the sliding limit structure is selected from a group consisting of a protruding portion, a ridge, and a groove.

3. The adjustable support as described in claim 2, wherein an out portion of each sliding limit structure is made of flexible and high friction material which is selected from a group consisting of silicone, rubber, plastic, thermoplastic polyurethane material.

4. The adjustable support as described in claim 1, wherein at least part of each sliding limit structure or each frame is made of magnetic material which is configured to attract the lower edge of the electronic device to the selected sliding limit structure, to maintain the electronic device at a fixed viewing angle when the lower edge of the electronic device is stopped at the selected sliding limit structure.

5. The adjustable support as described in claim 1, wherein each of the second frame and the third frame defines a notch on a free end portion thereof, the notch is configured to grip the electronic device when a rear surface of the electronic device is in contact with the end portion which has the notch, allowing the electronic device to be maintained at a fixed viewing angle.

6. The adjustable support as described in claim 1, wherein the first frame has an overall length and width slightly greater than those of the electronic device, and the second and third frames have a combined overall length and width slightly greater than those of the electronic device; wherein the first, second and third frames are further configurable into at least the following positions:
a third position in which the first frame covers one surface of the electronic device, and the second and third frames are connected together and cover an opposing surface of the electronic device; and
a fourth position in which the first frame covers one surface of the electronic device, and the second and third frames are folded together with the first frame.

7. An adjustable support for supporting an electronic device having a length and width, comprising:
a first frame having an overall length and width slightly greater than those of the electronic device; and
second and third frames having a combined overall length and width slightly greater than those of the electronic device;
wherein the second frame and the third frame rotatably connected to two opposite end portions of the first frame; the first, second and third frames are configurable into at least the following positions:
a first position in which the first frame covers one surface of the electronic device, the second and third frames are connected together and cover an opposing surface of the electronic device; and
a second position in which the first frame covers one surface of the electronic device, and the second and third frames are folded together with the first frame.

8. The adjustable support as described in claim 7, wherein each of the frames comprises a plurality of sliding limit structures on one surface of each frame.

9. The adjustable support as described in claim 8, wherein the first, second and third frames are further configurable into at least the following positions:
a third position in which the first and second frames are flat and the third frame is at a non-zero angle to the first frame, wherein the first or second frame supports the lower edge of the electronic device with a selected sliding limit structure of the first or second frame stopping the lower edge of the electronic device, and the third frame acts as a back stand for the electronic device; and
a fourth position in which the first and the third frames are flat and the second frame is at a non-zero angle to the first frame, wherein the first or third frame supports the lower edge of the electronic device with a selected sliding limit structure of the first or third frame stopping the lower edge of the electronic device, and the second frame acts as a back stand for the electronic device.

10. The adjustable support as described in claim 9, wherein the sliding limit structure is selected from a group consisting of a protruding portion, a ridge, and a groove.

11. The adjustable support as described in claim 9, wherein an out portion of each sliding limit structure is made of flexible and high friction material which is selected from a group consisting of silicone, rubber, plastic, thermoplastic polyurethane material.

12. The adjustable support as described in claim 9, wherein at least part of each sliding limit structure or each frame is made of magnetic material which is configured to attract the lower edge of the electronic device to the selected sliding limit structure, to maintain the electronic device at a fixed viewing angle when the lower edge of the electronic device is stopped at the selected sliding limit structure.

13. The adjustable support as described in claim 9, wherein each of the second frame and the third frame defines a notch on a free end portion thereof, the notch is configured to grip the electronic device when a rear surface of the electronic device is in contact with the end portion which has the notch, allowing the electronic device to be maintained at a fixed viewing angle.
